(19) United States
(12) Patent Application Publication
(10) Pub. No.: US 2021/0408353 A1
(43) Pub. Date: Dec. 30, 2021

(54) HEAT SINK SHIELD AND THERMOELECTRIC FAN WITH HEAT SINK SHIELD

(71) Applicant: Caframo Ltd., Georgian Bluffs (CA)

(72) Inventors: Dale SCHNURR, Georgian Bluffs (CA); Dalvir MALL, Georgian Bluffs (CA)

(21) Appl. No.: 17/471,830

(22) Filed: Sep. 10, 2021

Related U.S. Application Data
(63) Continuation of application No. PCT/CA2020/050333, filed on Mar. 12, 2020.
(60) Provisional application No. 62/817,261, filed on Mar. 12, 2019.

(51) Int. Cl. H01L 35/30; F04D 25/06; F04D 29/58

(52) U.S. Cl. CPC H01L 35/30; F04D 29/5853; F04D 25/06

(57) ABSTRACT

A thermoelectric fan including: a heat collector; a thermoelectric generator (TEG) thermally coupled to the heat collector; a heat sink thermally coupled to the TEG and positioned to provide a temperature differential across the TEG; a motor in electrical communication with the TEG; a fan blade coupled to the motor and configured to generate a first airflow through the heat sink; and a heat sink shield configured to shield the heat sink from a second airflow, the second airflow having a higher temperature than the first airflow. The second airflow may be generated by the fan blade interacting with the first airflow. A heat sink shield for a thermoelectric fan wherein the heat sink shield is configured to attach to the thermoelectric fan and configured to at least partially shield the heat sink from a vorticity vector field and related air flows generated by the fan blade.

### TECHNICAL FIELD

The present disclosure relates generally to a thermoelectric fan, sometimes referred to as a heat powered fan, which can be placed on the surface of a heat source, such as a wood or gas stove, and more particulary to a thermoelectric fan having a heat sink shield.

### BACKGROUND

Conventional heat powered fans have proven useful in dispersing warm air created by a heat source such as a wood stove or similar device. These fans automatically circulate air to allow a greater area to be warmed more quickly than just letting the heat radiate from the heat source directly. These fans are convenient in that they generate the energy needed to power the fan from the heat source itself.

Conventional heat powered fans may be limited in how much electrical energy they are able to generate. As such, there is an ongoing need for improved heat powered or thermoelectric fans.

### SUMMARY

Embodiments herein are intended to overcome at least one problem with conventional thermoelectic fans.

According to an aspect herein, there is provided a thermoelectric fan including: a heat collector; a thermoelectric generator (TEG) thermally coupled to the heat collector; a heat sink thermally coupled to the TEG and positioned in relation to the heat collector to provide a temperature differential across the TEG; a motor in electrical communication with the TEG; a fan blade coupled to the motor and configured to generate a first airflow through the heat sink; and a heat sink shield configured to shield the heat sink from a second airflow, the second airflow having a higher temperature than the first airflow.

In some cases, the heat sink shield redirects the second airflow away from the heat sink. In some cases, the heat sink shield blocks the second airflow from reaching the heat sink directly. In some cases, the heat sink shield covers the heat sink, or at least a predetermined central portion thereof. In some cases, the heat sink shield may be just large enough to cover the heat sink. In some cases, an area of the heat sink shield may be be larger than a cross-sectional area of the heat shield to provide an umbrella-like effect or a partial umbrella-like effect.

In some cases, the second airflow may be at least a portion of a vorticity field formed by the fan blade and the first airflow.

In some cases, the heat sink shield and the heat sink may be formed as a single contiguous body.

In some cases, the heat sink may include a plurality of fins and the heat sink shield may be connected to the thermoelectric fan in a way that is thermally insulated from the plurality of fins. In this case, the plurality of fins may be oriented parallel to a direction of flow of the first airflow.

In some cases, the heat sink shield has an inverted U-shaped rectangular cross section. In some cases, the heat sink shield may have a dimension in a first direction equal to a dimension of the heat sink in the first direction, the first direction parallel to a direction of flow of the first airflow.

In some cases, the heat sink shield may be made of the same material as the heat sink. In some cases, the heat sink shield may be made of a thermal insulating material.

In some cases, the heat sink shield may be positioned at a height at least approximately equal to a maximum height of the fan blade.

According to an aspect herein, there is provided a heat sink shield for a thermoelectric fan including a heat sink and a fan blade configured to generate a first airflow through the heat sink, the heat sink shield including: a body substantially impermeable to air and couplable to the thermoelectric fan and configured to redirect a second airflow away from the heat sink, the second airflow having a higher temperature than the first airflow.

In some cases, the second airflow is at least a portion of a vorticity field formed by the fan blade and the first airflow.

In some cases, the heat sink shield and the heat sink form a single contiguous body.

In some cases, the heat sink may include a plurality of fins and the heat sink shield may be connected to the thermoelectric fan in a way that is thermally insulated from the plurality of fins.

In some cases, the heat sink shield is configured to attach to the thermoelectric fan at a height at least approximately equal to a maximum height of the fan blade in relation to the thermoelectric fan.

According to an aspect herein, there is provided a heat sink shield for a thermoelectric fan including a heat sink and a fan blade, the heat sink shield configured to attach to the thermoelectric fan and configured to at least partially shield the heat sink from a vorticity vector field and related air flows generated by the fan blade.

In some cases, the heat sink shield may include a hemicylindrical cover that is placed above the fins of the heat sink.

### BRIEF DESCRIPTION OF THE DRAWINGS

Embodiments of the present disclosure will now be described, by way of example only, with reference to the attached Figures.

FIG. 1A illustrates an elevated perspective view of a thermoelectric fan according to an embodiment;

FIG. 1B illustrates a left view of the thermoelectric fan of FIG. 1A;

FIG. 1C illustrates a front view of the thermoelectric fan of FIG. 1A;

FIG. 1D illustrates a right view of the thermoelectric fan of FIG. 1A;

FIG. 1E illustrates a back view of the thermoelectric fan of FIG. 1A;

FIG. 1F illustrates a top view of the thermoelectric fan of FIG. 1A;

FIG. 1G illustrates a bottom view of the thermoelectric fan of FIG. 1A;

FIG. 2A illustrates a perspective view of a thermoelectric fan heatsink according to an embodiment, with elements of the thermoelectic fan shown in dotted lines;

FIG. 2B illustrates a left view of the thermoelectric fan heat sink of FIG. 2A;

FIG. 2C illustrates a front view of the thermoelectric fan heat sink of FIG. 2A;

FIG. 2D illustrates a right view of the thermoelectric fan heat sink of FIG. 2A;

FIG. 2E illustrates a back view of the thermoelectric fan heat sink of FIG. 2A;

FIG. 2F illustrates a top view of the thermoelectric fan heat sink of FIG. 2A;

FIG. 3 illustrates a perspective view of a thermoelectric fan heat sink according to an embodiment;

FIG. 4A illustrates a perspective view of a base of a thermoelectric fan according to an embodiment;

FIG. 4B illustrates a side view of the base of FIG. 4A;

FIG. 5A illustrates a perspective view of a thermoelectric fan according to an embodiment;

FIG. 5B illustrates a left view of the thermoelectric fan of FIG. 5A;

FIG. 5C illustrates a front view of the thermoelectric fan of FIG. 5A;

FIG. 5D illustrates a right view of the thermoelectric fan of FIG. 5A;

FIG. 5E illustrates a back view of the thermoelectric fan of FIG. 5A;

FIG. 5F illustrates a top view of the thermoelectric fan of FIG. 5A;

FIG. 5G illustrates a bottom view of the thermoelectric fan of FIG. 5A;

FIG. 6A illustrates a perspective view of a base of a thermoelectric fan according to an embodiment;

FIG. 6B illustrates a side view of the base of FIG. 6A;

FIG. 7A illustrates a front view of an embodiment of a thermoelectric fan showing a vorticity vector field and temperature gradients;

FIG. 7B illustrates a side view of an embodiment of a thermoelectric fan showing a vorticity vector field and temperature gradients;

FIG. 8 illustrates temperature differences for an embodiment of a thermoelectric fan;

FIG. 9 illustrates temperature differences for a conventional thermoelectric fan with an 8 inch fan blade; and

FIG. 10 illustrates temperature differences for a conventional thermoelectric fan with a 9 inch fan blade.

### DETAILED DESCRIPTION

According to various embodiments herein, there is generally provided a thermoelectric fan that includes a heat collecting element or base, a thermoelectric module, a heat sink, and a shield for the heat sink (sometimes referred to as a heat sink shield).

The trend with respect to wood stoves is towards more efficient combustion and reduced surface temperatures, which drives the design of thermal electrically powered wood stove fans toward lower operating temperatures, while attempting to maintain or increase overall performance in terms of speed and resulting airflow. There is also an on-going requirement to reduce cost.

Typically, thermoelectric fans include five general components; a heat collector or base, a thermoelectric module, a heat sink or top, a motor, and a blade. The function of the base is to conduct heat from a hot surface to the hot side of the thermoelectric module. The heat sink is placed above the thermoelectric module and creates a temperature differential across the thermoelectric module, which generates electricity to drive the motor and turn the blade. Thermal transfer takes place by means of conduction, convection, or radiation, and, in the case of thermoelectric wood stove fans, a combination of all three. In this application, although the base can be subjected to some thermal losses through convection and radiation to the surrounding environment, the resulting thermal energy that reaches the hot side of the thermoelectric module is conducted through the thermoelectric generator (TEG) module to the top extrusion (heat sink). The amount of heat conducted through the thermoelectric module is dependent upon the temperature gradient between the base and heat sink. The greater the temperature difference, the more thermal energy is conducted through the thermoelectric module and the greater the amount of electrical energy generated. Typically, the heat sink conducts the heat from the cold (upper in this case) side of the thermoelectric module through a series of projections or fins and then dissipates the thermal energy to the surrounding atmosphere by means of convection and radiation. The convection is at least in part a result of airflow generated by the rotation of the blade being swept across the vertical fins. The fins generally extend to the tip of the blade/airflow profile. It will be understood that, the more efficient the heat sink is, the lower the temperature at the heat sink side of the thermoelectric module and thus, the more electrical energy that can be produced.

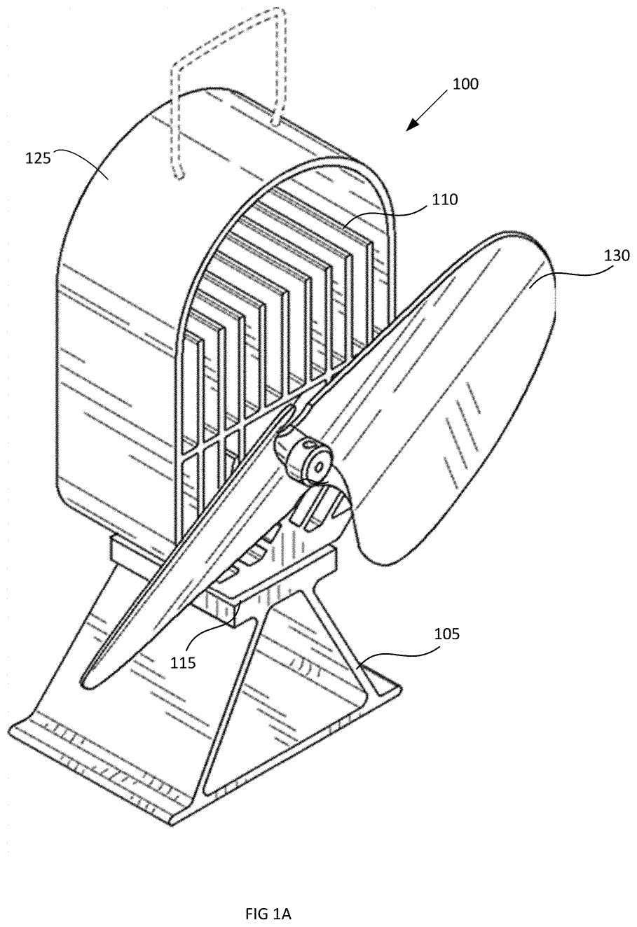

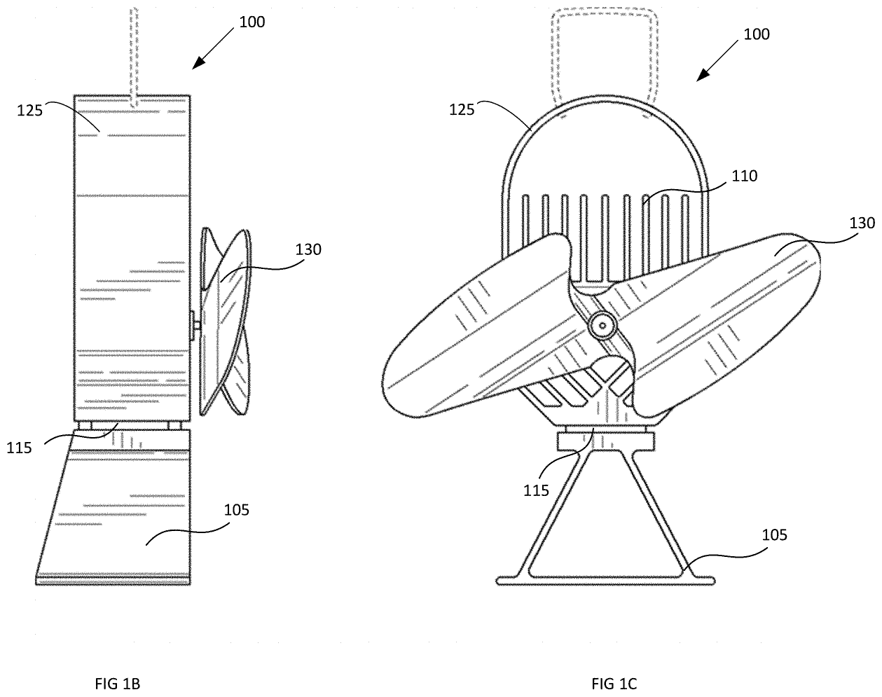

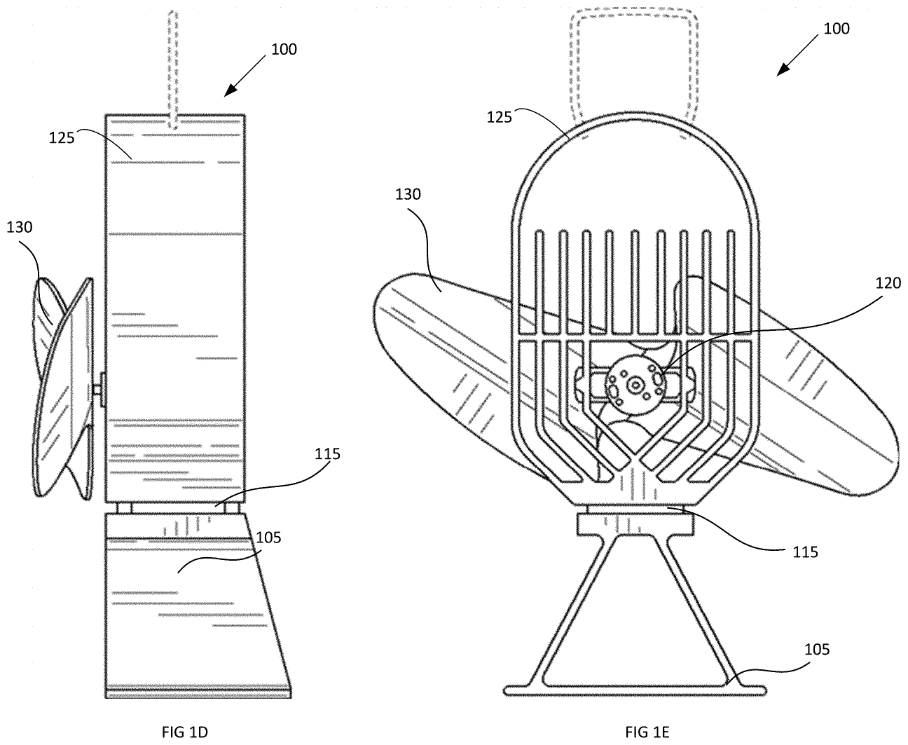

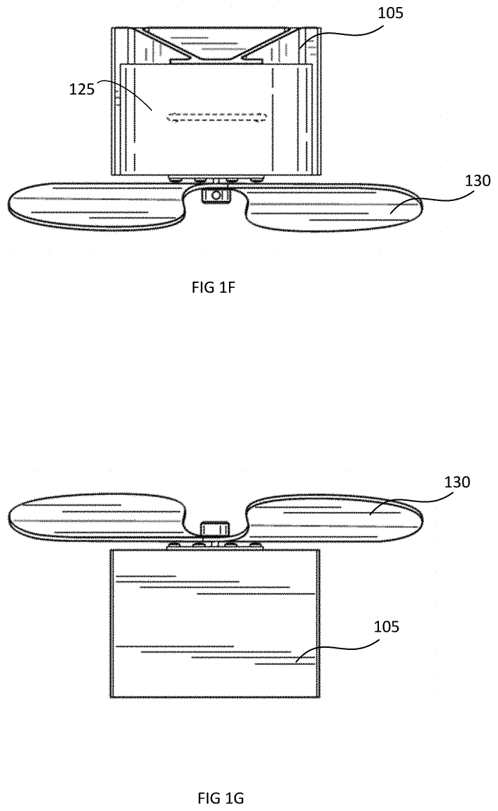

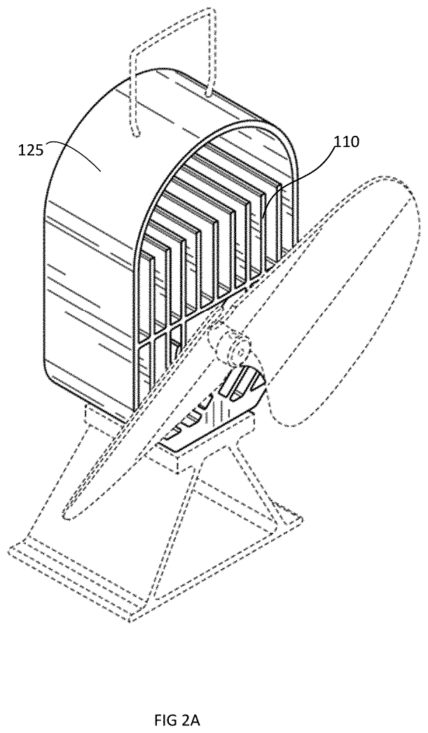

FIGS. 1A to 1G illustrate an embodiment of a thermoelectric fan 100. The thermoelectric fan 100 includes a heat collecting base 105, a heat sink 110, a thermoelectric generator (TEG) module 115, a motor 120, a heat sink shield 125, and a fan blade 130. In some cases, the thermoelectric fan 100 may include a handle (shown in dotted lines). The heat collecting base 105 of the fan 100 supports the TEG module 115 and provides a hot surface contact for the TEG module 115. The TEG module 115 is located between the heat sink 110 and the heat collecting base 105. The heat sink 110 includes a plurality of fins or projections 135, in this case, extending vertically, which are intended to allow the heat sink to provide a lower temperature on the top surface (i.e. cold side) of the TEG module 115. In this case, the fins 135 are covered by the heat sink shield 125. The fins 135 may be oriented parallel to a direction of flow of air generated by the fan blade 130. The heat collecting base 105 provides a higher temperature on the lower surface or hot side of the TEG module 115. Based on a temperature differential between the hotter and colder surface contacts, the TEG module 115 will generate power, which is supplied to the motor 120, to effect rotation of the fan blade 130.

The heat sink shield 125 is configured to cover to the fins (sometimes, projections) 135 to provide a shield against warm airflow that can be generated by the fan blade 130. The heat sink shield 125 in this embodiment is an arc-shaped structure that extends from one side of the heat sink over the fins 135 to the other side of the heat sink 110. In some cases, the heat sink shield may be made of a material to be impermeable to air so that the heat sink shied blocks a flow of air from above the heat sink downward toward the heat sink. In some cases, the heat sink shield may be configued to allow air to flow around and/or past the surfaces of the heat sink fins from other directions than above. The fan blade may have a size and may be positioned to extend above the heat sink shield or may end at a similar height to the heat sink shield. Generally speaking, the heat sink shield 125 is intended to disconnect or thermally isolate the fins from air flow (for example, a top ribbon and a vorticity vector field) generated by the fan blade as described in further detail herein.

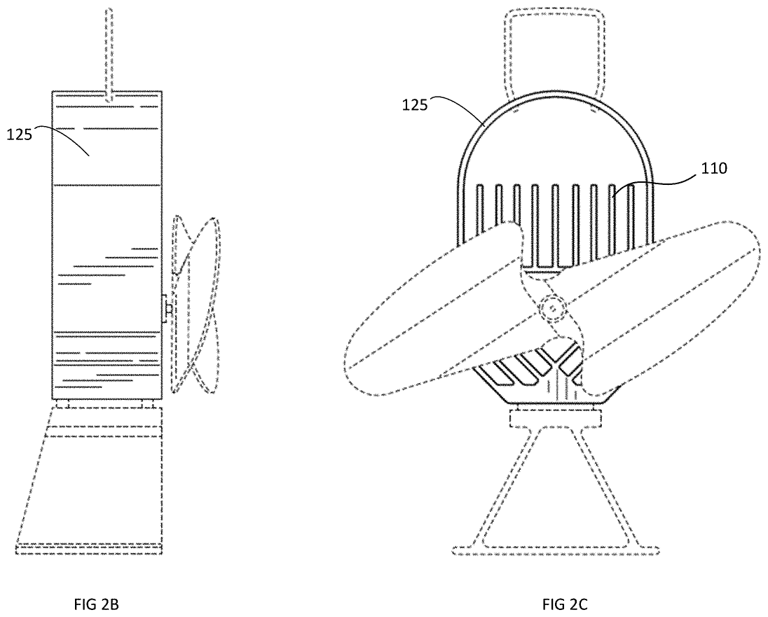

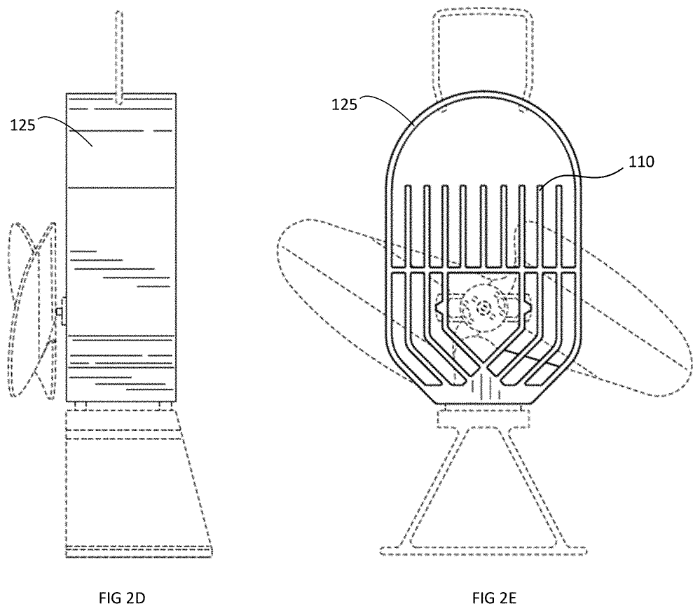

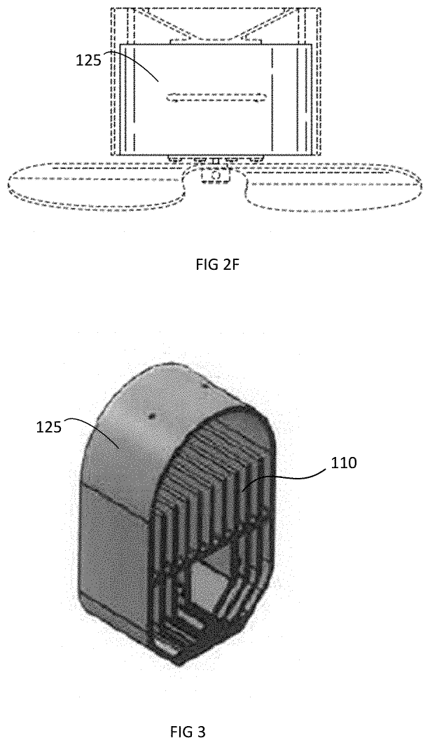

FIGS. 2A to 2F and FIG. 3 show additional detail of an embodiment of a heat sink similar to that shown in FIG. 1A.

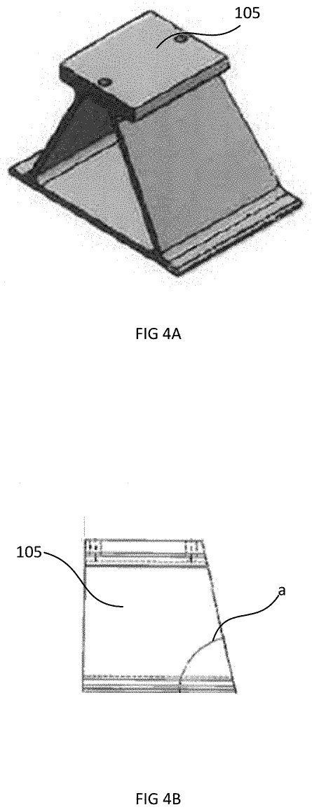

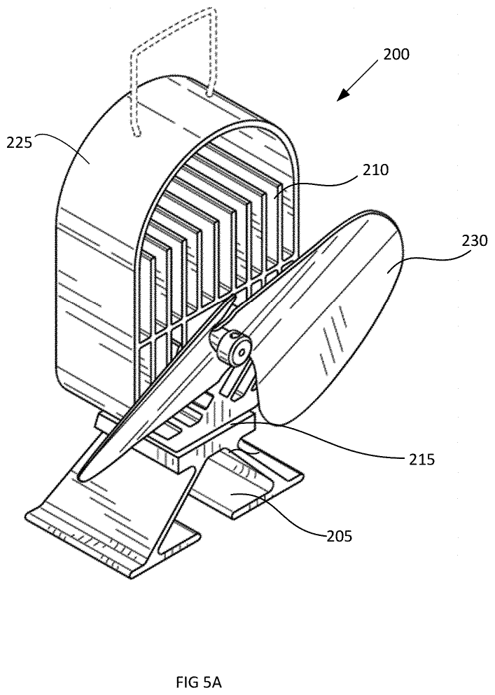

FIGS. 4A and 4B show additional detail of an embodiment of a base similar to that shown in FIG. 1A. As shown in FIG. 4B, the base includes an angled back side with an internal angle “a”. In some cases, the internal angle “a” is between 65 and 90 degrees. In some cases, the internal angle may be between 70 and 80 degrees. Among other benefits, the use of an angled base can provide for additonal contact with the hot surface (wood stove) and thus additional heat buildup in the base.

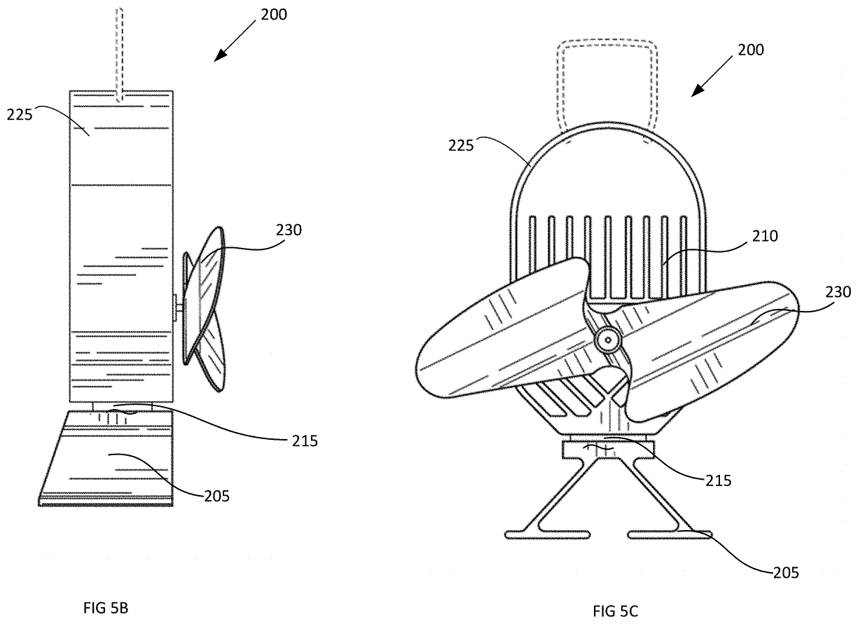

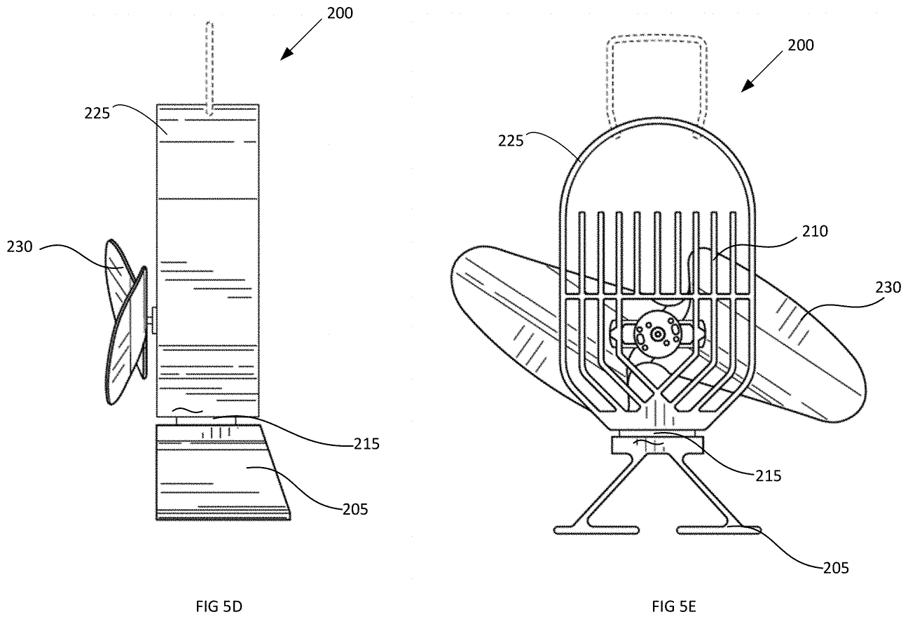

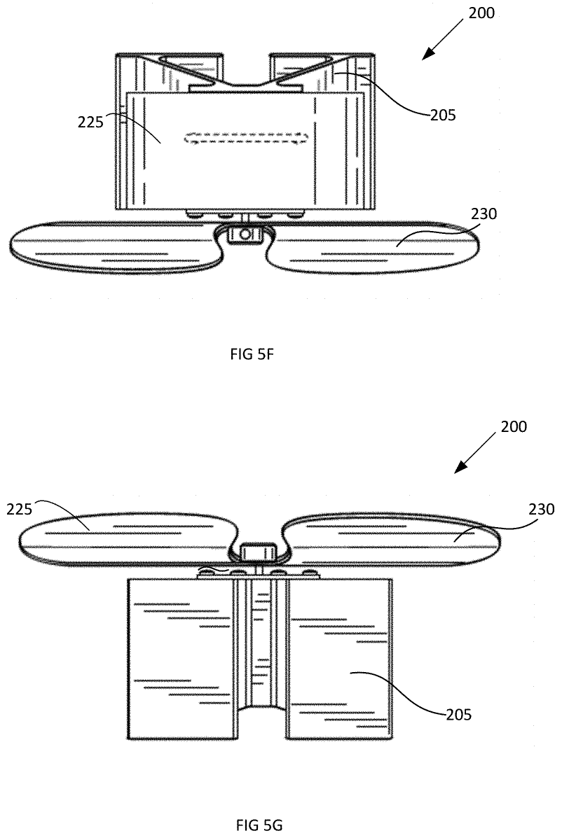

FIGS. 5A to 5G illustrate another embodiment of a thermoelectric fan 200. The thermoelectric fan 200 is similar to the thermoelectric fan 100. The thermoelectric fan 200 includes a heat collecting base 205, a heat sink 210, a thermoelectric generator (TEG) module 215, a motor 220, a heat sink shield 225, and a fan blade 230. The base 205 may include two angled legs and feet, where the feet may be placed on a hot surface, for example the surface of a wood or gas stove. The feet from the heat collecting base 205 conduct heat to the lower surface of the TEG module 215, while the heat sink 210 includes fins 235 to allow the heat sink 210 to provide a lower temperature for the top surface of the TEG module 215. The power generated by the TEG module 215 is supplied to the motor 220 to rotate the fan blade 230. The fan blade 230 may extend to a similar height as the heat sink shield or may extend past the heat sink shield. Similar to the thermoelectric fan 100, the heat sink shield 225 is configured to cover the fins 235 of the heat sink 210 and shield them from at least some of the hot air that may circulate due to the rotation of the fan blade 230.

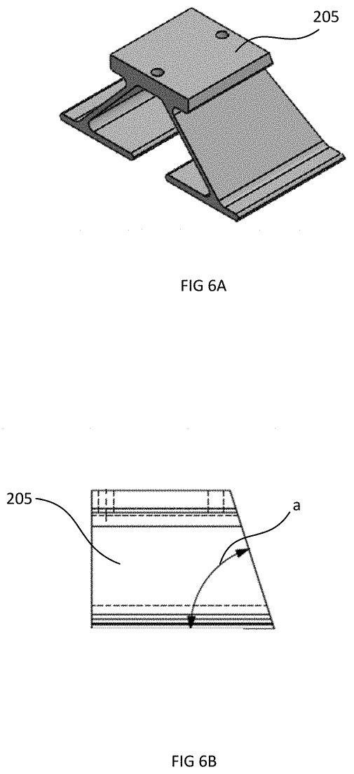

FIGS. 6A and 6B show additional detail of an embodiment of a base similar to that shown in FIG. 5A. As shown in FIG. 6B, the base includes an angled back side with an internal angle “a”, similar to the base shown in FIGS. 4A and 4B.

In reviewing conventional thermoelectric fans, it was noticed that heat may be unexpectedly directed to the heat sink when the thermoelectric fan is operating. In particular, a vorticity vector field generated by the rotation of the blades was examined. Unexpectedly, fluid/gas in the vorticity vector field can receive heat energy from the nearby hot surface and the temperature of the fluid/gas in the vorticity vector field may be significantly higher than other air in the vicinity of the fan and, in particular, the incoming air from the rear of the fan. The direction of the incoming air is generally perpendicular to the vorticity vector field, which results in the generation of a vortex and curls (i.e. additional flows of air outside of the vortex near the fan blade). In this document, the vortex and curls may be referred to as the vorticity vector field. The vortex and the curls may draw hot air (fluid/gas) into a circular pattern. The temperature of the air in curls may be lower than in the vortex it self but may still be significantly higher than, for example, air to the rear of the fan and other surrounding air. In a conventional fan, the hot air in the vorticity vector field may interact with the top of the heat sink, which may increase the overall temperature of the heat sink.

Through experimentation, the heat created by the vorticity vector field was measured. Previously, the temperature change over the vertical fins of the heat sink was not considered to produce significant effect on the electrical energy generated by the thermoelectric fan, however, surprisingly, the effect was significant.

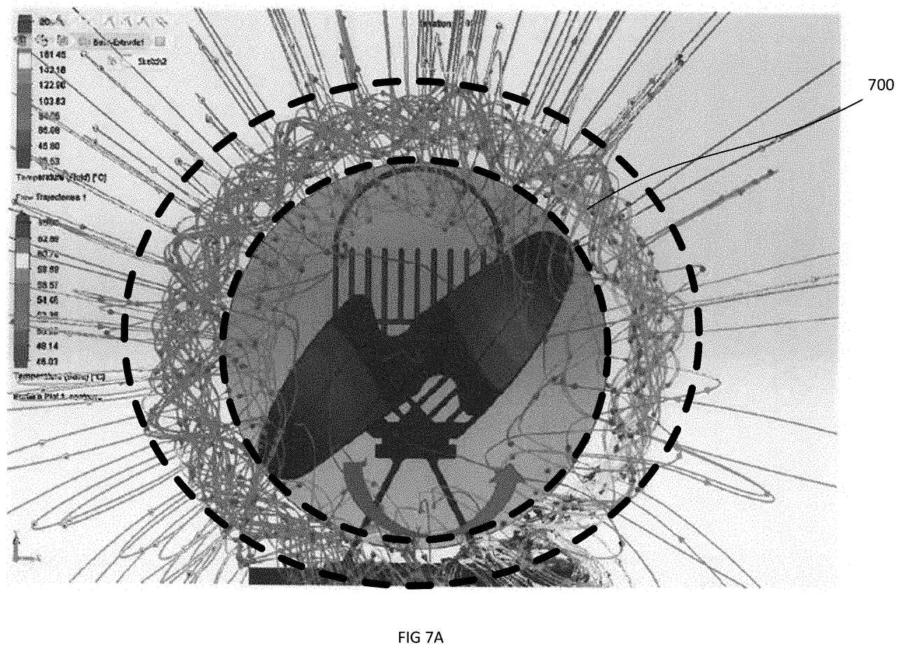

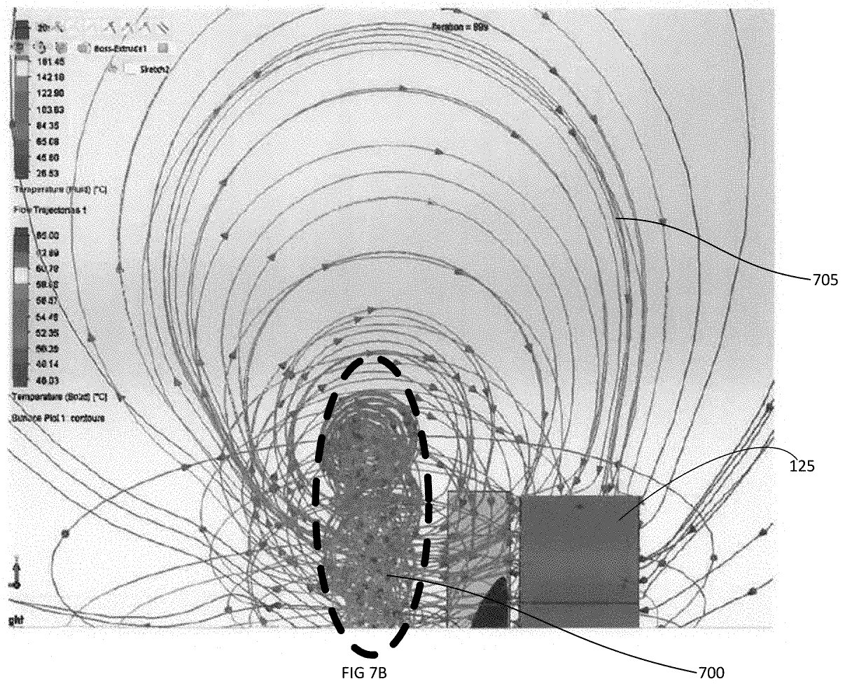

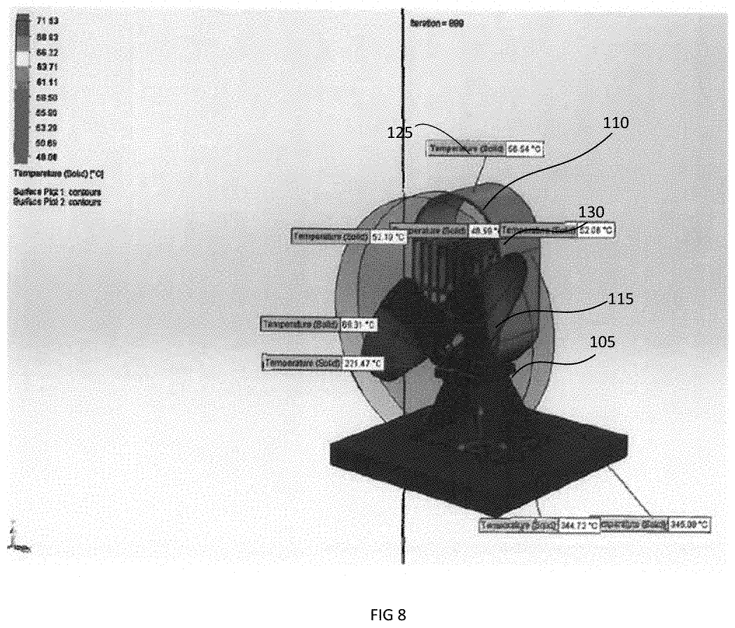

The experimentation noted above determined the effect of the temperature in the vorticity vector field and curls and further experimentation, as illustrated in FIGS. 7A and 7B, led to the present embodiments in which a heat sink shield covers/protects the heat sink from the vortices and curls. FIG. 7A is a front view and FIG. 7B is a side view illustrating the thermoelectric fan 100, a vorticity vector field 800 and 805, and temperature gradient. As shown in FIGS. 7A and 7B, vortex 700 and curls 705 contain air having a higher temperature than ambient air typically pulled across the heat sink 110 by fan blade 130. Heat sink shield 125 is intended to increase the efficiency of thermoelectric fan 100 by preventing or reducing the amount of the hot air in the vortex 800 and/or curls 805 from contacting the heat sink 110 or redirecting the hot air in the vortex 800 and/or curls 805 away from the heat sink 110. This was surprising, as typically any increase in airflow across a heat sink would be expected to increase the rate of heat dissipation of the heat sink. Therefore, a shield that prevents airflow from reaching or directs air away from the heat sink would be expected to decrease efficiency. However, due to the unexpectedly high temperature of the air in the vorticity vector field, the blocking or redirection of air by the heat sink shield 125 has an unexpected effect.

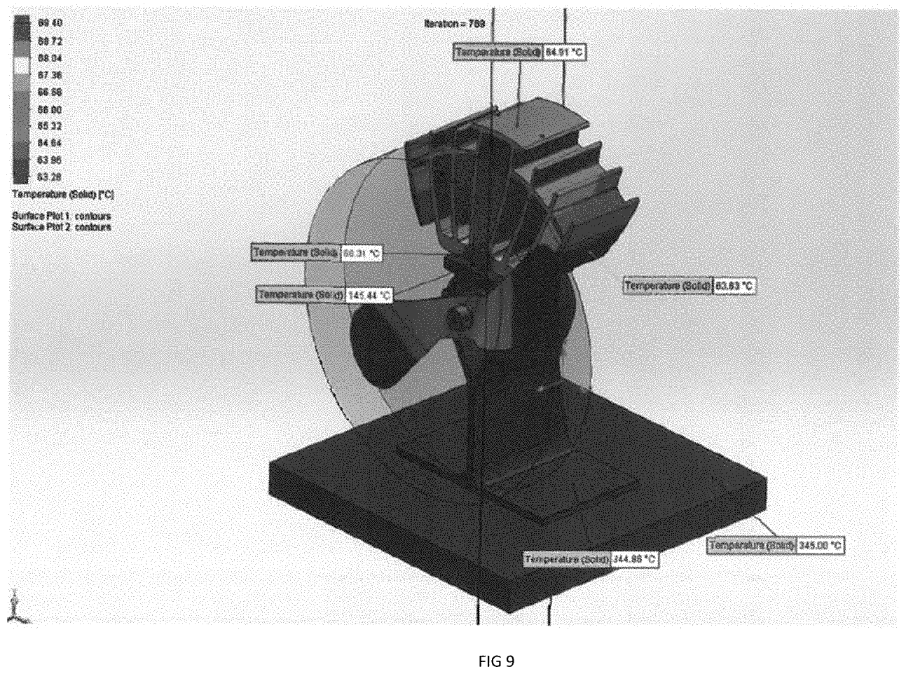

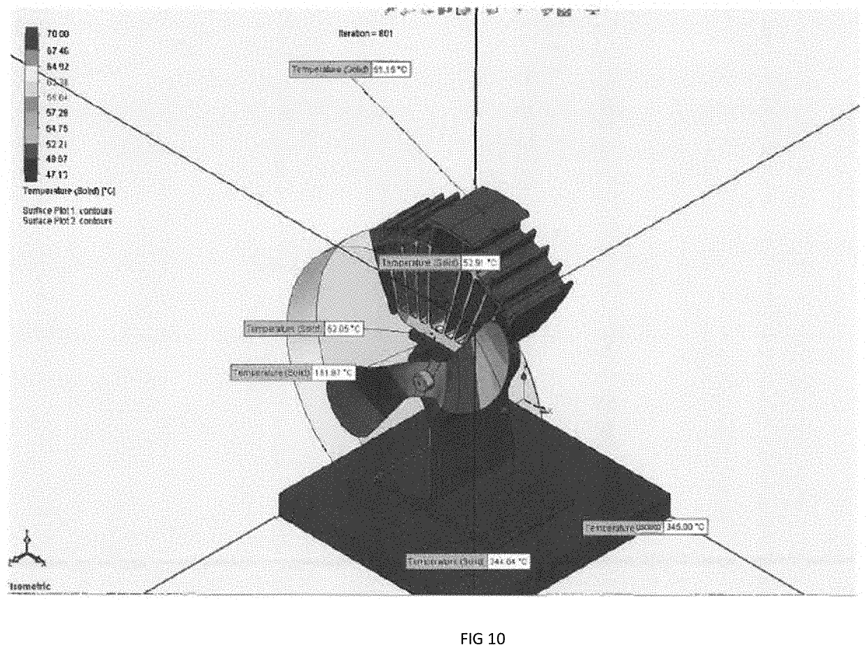

In reference to FIGS. 8 and 9 and 10, it was observed that the temperature at the tip of the vertical fins is higher in conventional models of the thermoelectric fan (FIGS. 9 and 10) when compared to a fan having the heat sink shield (FIG. 8). In particular, FIG. 8 illustrates temperature differentials for an embodiment of a thermoelectric fan 100 having a heat sink shield 125. FIGS. 9 and 10 illustrate temperature differentials for conventional thermoelectric fans (which conventionally do not include a heat sink shield) having different sizes of fan blade. In FIGS. 9 and 10, the thermoelectric fan has a heat sink design that incorporates a further fin arranged as a horizontal arc or ribbon at the tops of vertical fins. However, due to the thermal connection and proximity between this horizontal fin and the vertical fins, there is generally not a shielding effect such as that in the embodiment shown in FIG. 8.

In some embodiments, the impact of the heat transfer from the curls/vortices may be reduced or minimized by thermally isolating or separating the heat sink shield from the vertical fins of the heat sink. Thermal isolation may be achieved by coupling the heat sink shield to the heat sink or the fins via a material having low thermal conductivity. Thermal isolation may be achieved by coupling the heat sink shield in a way that is separated from the fins. For example by providing a separate attachment point to the heat sink closer to the TEG module or the like. In some embodiments, the heat sink shield can be formed integrally with the outer parts of the heat sink as an extrusion, via a mold, or the like at the same time as forming the heat sink.

By including a heat sink shield with an inverted U-shaped rectangular cross section that is separated from the fins, for example the heat sink shield 125, improved results were achieved. In some embodiments, the heat sink shield may allow for the fins of the heat sink to be shorter in length but provide at least a similar efficiency. Other geometric arc shapes that are configured to cover/protect the vertical fins will likely have similar results as the shield shown in the embodiments described herein. In some embodiments, the heat sink shield may be configured to have dimensions in a horizontal plane to match with the dimensions of the heat sink in that horizontal plane so that the heat sink shield just covers the fins of the heat sink. In other embodiments, the heat sink shield may overhang the fins of the heat sink on a front, back or sides of the heat sink by a predetermined percentage, for example 1%, 5%, 10% or the like.

Generally speaking, the heat sink shield is intended to shield or protect the vertical fins from hot air eddies/curls/vorticies as can be seen in FIGS. 8A and 8B. The shield may be part of an extruded heat sink and may be the same material as the heat sink. The heat shield may be a separate part which may be attached over the fins and constructed of various materials, for example, high temperature plastics, stainless steel, Bakelite and the like, depending on the temperatures and other characteristics involved for the fan.

In some embodiments, the heat shield will not be thermally connected to the heat sink (or, at least the central fins of the heat sink). As shown in some embodiments herein, the heat sink shield may be connected to the outermost of the heat sink fins. The heat sink shield may be connected in various ways, such as to the base of the heat sink, via thermal insulating clamps to the fins, possibly even to the base or the hot surface below the base (via thermal insulating devices or means, where possible), or the like. In any of these cases, the heat sink shield can still be configured to cover/protect the fins from being further warmed by the vorticity vector field. At higher surface temperatures, which would increase the temperature of the air in the vorticity vector field, the effect may be more pronounced. By including the heat sink shield with the thermoelectric fan, the fins (or at least the central fins) of the heat sink may dissipate more heat into the air or may be shorter in length with the same level of dissipation. The dissipation of heat increases the temperature gradient and allows for a lower temperature at the cold side of the TEM. As noted above, FIG. 8 illustrates the temperature differentials in the thermoelectric fan 100 and in comparison to FIGS. 9 and 10 illustrating the temperature differentials of conventional thermoelectric fans.

In the preceding description, for purposes of explanation, numerous details are set forth in order to provide a thorough understanding of the embodiments. However, it will be apparent to one skilled in the art that these specific details may not be required. In other instances, well-known structures may be shown in block diagram form in order not to obscure the understanding.

The above-described embodiments are intended to be examples only. Those of skill in the art can effect alterations, modifications and variations to the particular embodiments, including taking elements from each embodiment in other embodiments or the like, without departing from the scope, which is defined solely by the claims appended hereto.

We claim:

1. A thermoelectric fan comprising:
a heat collector;
a thermoelectric generator (TEG) thermally coupled to the heat collector;
a heat sink thermally coupled to the TEG and positioned in relation to the heat collector to provide a temperature differential across the TEG;
a motor in electrical communication with the TEG;
a fan blade coupled to the motor and configured to generate a first airflow through the heat sink; and
a heat sink shield configured to redirect a second airflow away from the heat sink, the second airflow having a higher temperature than the first airflow.

2. The thermoelectric fan of claim 1, wherein the second airflow is at least a portion of a vorticity field formed by the fan blade and the first airflow.

3. The thermoelectric fan of claim 1, wherein the heat sink shield and the heat sink are formed as a single contiguous body.

4. The thermoelectric fan of claim 1, wherein the heat sink comprises a plurality of fins, and wherein the heat sink shield is connected to the thermoelectric fan in a way that is thermally insulated from the plurality of fins.

5. The thermoelectric fan of claim 4, wherein the plurality of fins are oriented parallel to a direction of flow of the first airflow.

6. The thermoelectric fan of claim 1, wherein the heat sink shield has an inverted U-shaped rectangular cross section.

7. The thermoelectric fan of claim 1, wherein the heat sink shield has a dimension in a first direction equal to a dimension of the heat sink in the first direction, the first direction parallel to a direction of flow of the first airflow.

8. The thermoelectric fan of claim 1, wherein the heat sink shield comprises the same material as the heat sink.

9. The thermoelectric fan of claim 1, wherein the heat sink shield is positioned at a height at least approximately equal to a maximum height of the fan blade.

10. A heat sink shield for a thermoelectric fan comprising a heat sink and a fan blade configured to generate a first airflow through the heat sink, the heat sink shield comprising:
a body substantially impermeable to air and couplable to the thermoelectric fan and configured to redirect a second airflow away from the heat sink, the second airflow having a higher temperature than the first airflow.

11. The thermoelectric fan of claim 10, wherein the second airflow is at least a portion of a vorticity field formed by the fan blade and the first airflow.

12. The thermoelectric fan of claim 10, wherein the heat sink shield and the heat sink form a single contiguous body.

13. The thermoelectric fan of claim 10, wherein the heat sink comprises a plurality of fins, and wherein the heat sink shield is connected to the thermoelectric fan in a way that is thermally insulated from the plurality of fins.

14. The thermoelectric fan of claim 10, wherein the heat sink shield is configured to attach to the thermoelectric fan at a height at least approximately equal to a maximum height of the fan blade.

15. A heat sink shield for a thermoelectric fan comprising a heat sink and a fan blade, the heat sink shield configured to attach to the thermoelectric fan and configured to at least partially shield the heat sink from a vorticity vector field and related air flows generated by the fan blade.
